(19) United States
(12) Patent Application Publication
(10) Pub. No.: US 2011/0127644 A1
(43) Pub. Date: Jun. 2, 2011

(54) WAFER AND METHOD FOR FORMING THE SAME

(75) Inventors: Hee Bok Kang, Cheongju (KR); Young Wug Kim, Seoul (KR); Si Choon Yeom, Chungcheongbuk-do (KR)

(73) Assignee: Hynix Semiconductor Inc., Icheon (KR)

(21) Appl. No.: 12/792,421

(22) Filed: Jun. 2, 2010

(30) Foreign Application Priority Data
Nov. 27, 2009 (KR) 10-2009-0115595

(51) Int. Cl. H01L 23/544; H01L 21/50; H01L 21/71

(52) U.S. Cl. 257/620; 438/106; 438/401; 257/E23.179; 257/E21.499; 257/E21.536

(57) ABSTRACT

A wafer and a method for forming the same are disclosed. The wafer forming method can separate respective chips from others by performing a Deep Reactive Ion Etching (DRIE) process on a wafer including a plurality of chips. The wafer includes a plurality of chips configured to be arranged in row and column directions on the wafer, a scribe region configured to be formed among the plurality of chips so as to separate each chip, and an alignment key pattern configured to be arranged on the plurality of chips.

### CROSS-REFERENCE TO RELATED APPLICATION

The priority of Korean patent application No. 10-2009-0115595 filed on Nov. 27, 2009, the disclosure of which is hereby incorporated in its entirety by reference, is claimed.

### BACKGROUND OF THE INVENTION

Embodiments of the present invention relate to a wafer and a method for forming the same, and more specifically, to a technology for separating each chip from a wafer including a plurality of chips.

A radio frequency identification (RFID) tag chip has been widely used to automatically identify objects using a radio frequency (RF) signal. In order to automatically identify an object using the RFID tag chip, an RFID tag is first attached to the object to be identified, and an RFID reader wirelessly communicates with the RFID tag of the object in such a manner that a non-contact automatic identification scheme can be implemented. With the widespread use of such RFID technologies, the shortcomings of related automatic identification technologies, such as barcode and optical character recognition technologies, can be greatly reduced.

Recently, the RFID tag has been widely used in physical distribution management systems, user authentication systems, electronic money (e-money), transportation systems, and the like.

For example, the physical distribution management system generally performs a classification of goods or management of goods in stock by storing data in an Integrated Circuit (IC) instead of using a delivery note or tag. In another example, the user authentication system generally performs an Entrance and Exit Management function using an IC card including personal information or the like.

In the meantime, a non-volatile ferroelectric memory may be used as a memory in an RFID tag.

Generally, a non-volatile ferroelectric memory [e.g., a Ferroelectric Random Access Memory (FeRAM)] has a data processing speed similar to that of a Dynamic Random Access Memory (DRAM). The non-volatile ferroelectric memory also preserves data even when power is turned off. Because of these properties many developers are conducting intensive research into FeRAM as a next generation memory device.

The above-mentioned FeRAM has a very similar structure to that of DRAM, and uses a ferroelectric capacitor as a memory device. The ferroelectric substance has high residual polarization characteristics, such that data is not lost although an electric field is removed.

In this case, the RFID device uses frequencies of various bands. In general, as the value of a frequency band is decreased, the RFID device has a slower recognition speed, has a shorter operating distance, and is less affected by the surrounding environment (e.g., disruption from WiFi, cellphones, etc.) In contrast, as the value of a frequency band is increased, the RFID device has a faster recognition speed, has a greater operating distance, and is considerably affected by the surrounding environment. It may also be difficult to tell when a connection is made with a RFID tag or the status of the communication. This is especially true when there are several RFID tags in close proximity.

A plurality of RFID chips is included in a wafer in rows and columns. In order to perform dicing of each RFID chip at a wafer level, laser sawing may be used.

In addition, mask align keys, each of which is used as a reference for separating individual RFID chips from one another, are formed on a scribe lane (also called a scribe line) of a wafer. In other words, the scribe lane on a wafer is sawed by a laser beam, such that individual RFID chips can be separated from one another. Therefore, a cutter for separating each chip is required for the sawing process, resulting in an increase in time and cost.

Also, in a conventional RFID device a mask align key is formed on a scribe lane, such that an interval between chips is increased due to the required area of a scribe lane. In other words, one scribe lane for separating each chip and another scribe lane for arranging align keys are widely arranged at intervals of the same distance, and these scribe lanes are arranged among respective chips. As a result, the number of net dies on a wafer is decreased.

### BRIEF SUMMARY OF THE INVENTION

Various embodiments of the present invention are directed to providing a wafer and a method for forming the same that substantially obviate one or more problems due to limitations and disadvantages of the related art.

An embodiment of the present invention relates to a wafer technology for allowing each memory chip to be diced using a Deep Reactive Ion Etching (DRIE) process without performing an additional sawing process on a wafer including a plurality of memory chips.

An embodiment of the present invention relates to a wafer technology for allowing each RFID chip to be diced using a DRIE process without performing an additional sawing process on a wafer including a plurality of memory chips.

An embodiment of the present invention relates to a wafer technology for reducing an area of a scribe lane which is used to separate each chip from a wafer.

An embodiment of the present invention relates to a wafer technology for arranging an align key for use in a backgrinding process on a chip, such that a scribe-lane area can be reduced.

An embodiment of the present invention relates to a wafer technology for simultaneously performing a DRIE process on an overall wafer, such that fabrication time and costs requisite for dicing a wafer can be greatly reduced.

In accordance with one embodiment of the present invention, a wafer includes a plurality of chips configured to be arranged in row and column directions on the wafer, a scribe lane configured to be formed among the plurality of chips so as to separate each chip, and an align key pattern configured to be arranged on the plurality of chips.

In accordance with two embodiment of the present invention, a wafer includes a chip areas being defined on a substrate, the substrate having a first side and a second side opposing the first side, a scribe region formed between the chip areas, and a first alignment key pattern formed in one of the chip areas, the first alignment key being detectable from the first and second sides of the substrate, wherein the first alignment key pattern extending vertically through the substrate.

In accordance with three embodiment of the present invention, a method for forming a wafer which includes a first chip area in which an align key pattern is formed, a second chip area, and a scribe lane for separating the first chip area and the second chip area from each other, includes forming the align key pattern on the first chip area of a semiconductor substrate, forming a circuit area on each of the first chip area of an upper part of the semiconductor substrate and the second chip area; forming a passivation layer on the circuit area, exposing the align key pattern by performing a backgrinding process at a back side of the semiconductor substrate, forming a first trench on the semiconductor substrate formed in the scribe lane, using a photoresist pattern as an etch mask, and performing a wafer mounting process on the semiconductor substrate including the first trench.

The above-mentioned exemplary embodiments of the present invention have the following characteristics.

First, a wafer and a method for forming the same according to one aspect of the present invention can allow each memory chip to be diced using a DRIE process without performing an additional sawing process on a wafer including a plurality of memory chips, resulting in reduction in fabrication time and costs.

Second, a wafer and a method for forming the same according to another aspect of the present invention can allow each RFID chip to be diced using a DRIE process without performing an additional sawing process on a wafer including a plurality of memory chips, resulting in reduction in fabrication time and costs.

Third, a wafer and a method for forming the same according to another aspect of the present invention can reduce an area of a scribe lane which is used to separate each chip on a wafer, such that the number of net dies is increased.

Fourth, a wafer and a method for forming the same according to another aspect of the present invention can arrange an align key for use in a backgrinding process on a chip, such that a scribe-lane area can be reduced.

Fifth, a wafer and a method for forming the same according to another aspect of the present invention can simultaneously perform a DRIE process on an overall wafer, such that fabrication time and costs requisite for wafer dicing can be greatly reduced.

It is to be understood that both the foregoing general description and the following detailed description of the present invention are exemplary and explanatory and are intended to provide further explanation of the invention as claimed.

It will be appreciated by persons skilled in the art that that the effects that can be achieved with the present invention are not limited to what has been particularly described hereinabove and other advantages of the present invention will be more clearly understood from the following detailed description taken in conjunction with the accompanying drawings.

### BRIEF DESCRIPTION OF THE DRAWINGS

FIG. 1 is a block diagram illustrating a Radio Frequency Identification (RFID) chip according to an embodiment of the present invention.

FIGS. 2 to 3 illustrate a method for forming a wafer according to an embodiment of the present invention.

FIGS. 4 to 16 are cross-sectional views illustrating a method for forming a wafer according to an embodiment of the present invention.

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts.

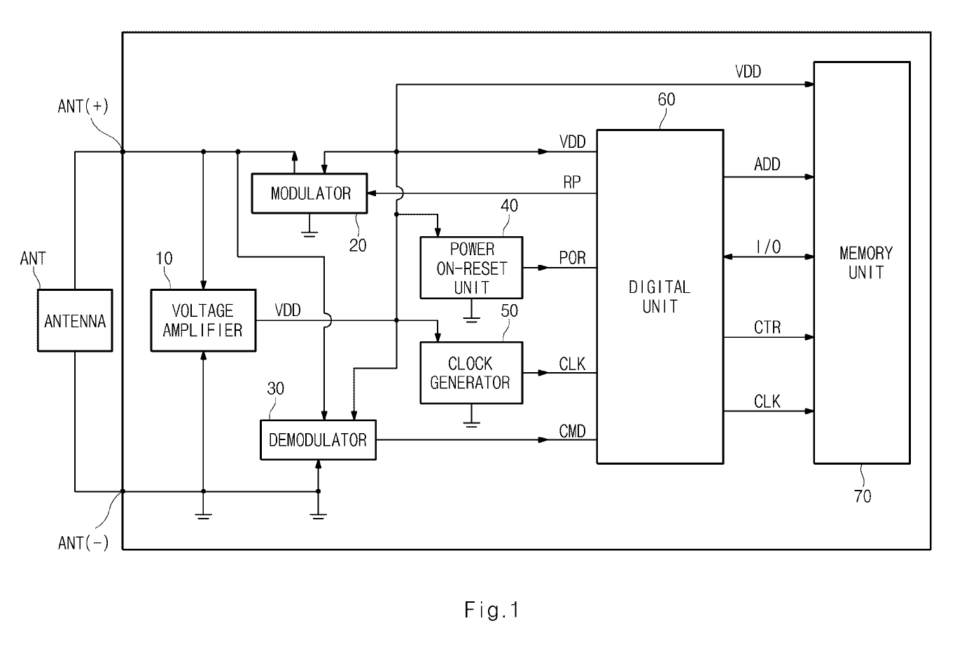

FIG. 1 is a block diagram illustrating a Radio Frequency Identification (RFID) chip according to an embodiment of the present invention.

Referring to FIG. 1, the RFID chip includes an antenna ANT, a voltage amplifier 10, a modulator 20, a demodulator 30, a power-on reset unit 40, a clock generator 50, a digital unit 60, and a memory unit 70.

In this case, the antenna ANT receives a radio frequency (RF) signal from an RFID reader. The RF signal received in the RFID device is input to the RFID chip via antenna pads ANT(+) and ANT(−).

The voltage amplifier 10 rectifies and boosts the RF signal received via the antenna ANT, and generates a power-supply voltage VDD serving as an RFID-device driving voltage.

The modulator 20 modulates a response signal RP received from the digital unit 60, and outputs the modulated response signal RP to the antenna ANT. The demodulator 30 demodulates the RF signal received from the antenna ANT in response to the output voltage of the voltage amplifier 10, and outputs a command signal CMD to the digital unit 60.

The power-on reset unit 40 detects a power-supply voltage generated in the voltage amplifier 10, and outputs a power-on reset signal POR to the digital unit 60 so as to control a reset operation in response to the detected power-supply voltage. In this case, detailed operation of the power-on reset signal POR are as follows. The power-on reset signal POR increases simultaneously with a power-supply voltage during a transition time in which the power-supply voltage changes from a low level to a high level. As soon as a power source reaches the power-supply voltage VDD, the power-on reset signal POR is changed from a high level to a low level, such that it is able to reset a circuit included in the RFID device.

The clock generator 50 outputs a clock signal CLK to the digital unit 60, wherein the clock signal CLK is capable of controlling operations of the digital unit 60 in response to the power-supply voltage VDD generated from the voltage amplifier 10.

The digital unit 60 receives a power-supply voltage VDD, a power-on reset signal POR, a clock signal CLK, and a command signal CMD, analyzes the command signal CMD, and generates a control signal and process signals. The digital unit 60 outputs a response signal RP corresponding to the control and process signals to the modulator 20. The digital unit 60 outputs an address ADD, input/output data I/O, a control signal CTR, and a clock signal CLK to the memory unit 70.

The memory unit 70 includes a plurality of memory cells. Each memory cell writes data in a storage unit, and reads the data therefrom.

In this case, the memory unit 70 may be a non-volatile ferroelectric memory (FeRAM). The FeRAM has a data processing speed similar to that of a DRAM. Also, the FeRAM has a structure very similar to that of DRAM, and uses a ferroelectric capacitor as a storage device so that the FeRAM has a high residual polarization characteristic. Due to the high residual polarization characteristics, data is not lost although an electric field is removed.

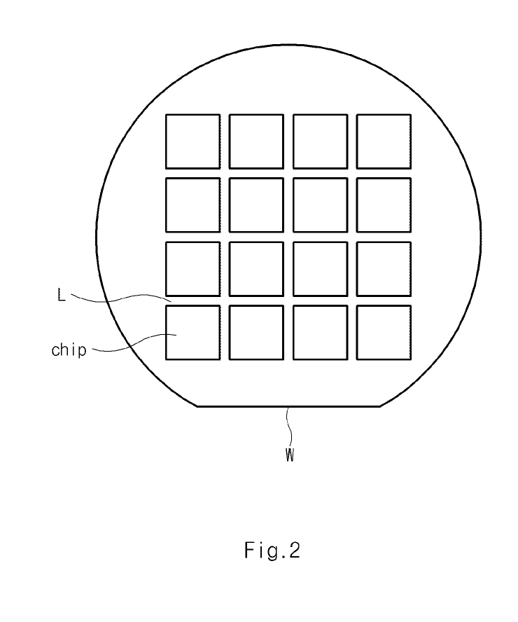

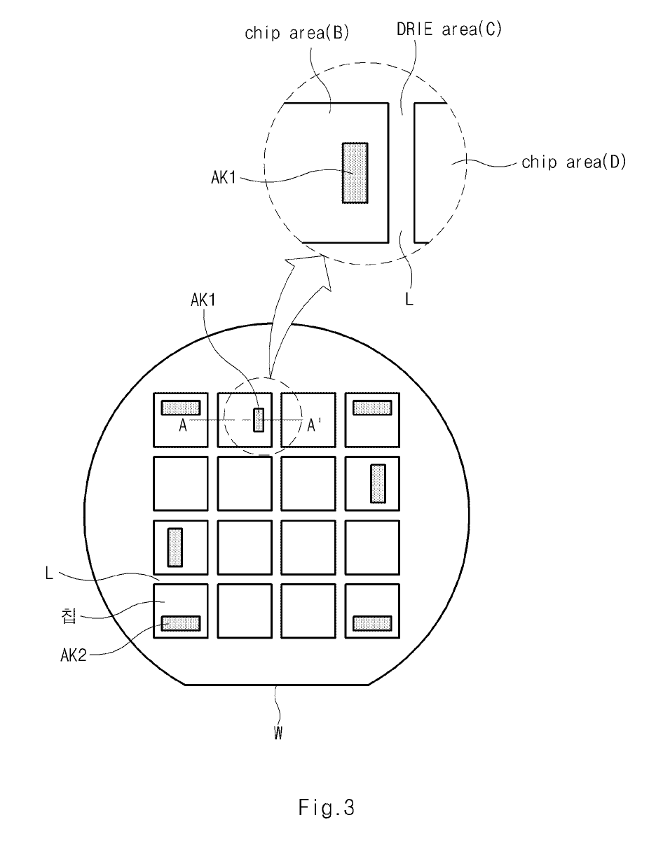

FIGS. 2 to 3 illustrate a method for forming a wafer according to an embodiment of the present invention. FIGS. 2 and 3 illustrate a cell array configuration and an align key configuration on a back side of a wafer.

Referring to FIGS. 2 and 3, a wafer according to an embodiment of the present invention may include an RFID chip, a DRAM, a FeRAM, or other memory chip, etc. For convenience of description and better understanding of the present invention, it is assumed that a wafer W has RFID chips.

A plurality of RFID tag chip areas D are arranged on a wafer W in rows and in columns. A scribe lane L is arranged among individual RFID areas D. Chips can be diced by a Deep Reactive Ion Etching (DRIE) process performed along the scribe lane L. According to the present invention, since a DRIE process is performed onto the scribe lane L, the scribe lane L is interchangeably referred to as DRIE area C, hereinafter.

A backside align key AK1 used for a photo process performed onto a back side of the wafer W is formed in a chip area of the wafer W, rather than in a scribe lane L. Although the backside align key AK1 is generally used for a photo-mask align key for a photo masking process performed onto the back side of the wafer W, it also can be used as an align key for a masking process performed onto a front side of the wafer W.

Optionally, a front-side align key AK2 may be formed in the chip area D for use in a masking process performed onto a front side of the wafer W. In this case, the front-side align key AK2 may be used to build up an integrated circuit in the chip area D.

In accordance with the above-mentioned embodiment of the present invention, the align key patterns AK1 and AK2 are not formed in a scribe lane L but in a chip area. Therefore, a scribe-lane area can be reduced, and thus the number of net dies per wafer can be increased.

Furthermore, according to an embodiment of the present invention, since a dicing process is not performed by a sawing process but by a DRIE process onto a back side of the wafer W, the scribe lane are can be further reduced.

The align key AK1 or AK2 may be arranged in a vertical and/or in a horizontal direction in the chip area D.

In this case, the front side align key AK2 is optional, and no align key AK2 may be formed, especially when the chip area D includes a CMOS circuit. When there is no front side align key AK2, the metal lines M1˜Mn forming the CMOS circuit may serve as an align key.

The backside align key AK1 formed in the chip area B can be used as a reference for forming a mask defining the scribe lane, i.e., the DRIE area C on the back side of the wafer W. That is, in reference to the back side align key AK1, a DRIE process is performed onto the back side of the wafer W in the DRIE area C.

In addition, a scribe lane L for separating each chip by a DRIE process with respect to the align key AK2 may correspond to a DRIE area C. The DRIE area C may correspond to an area for forming a trench needed when a wafer is cut by the DRIE process at a back side of the wafer. An area for constructing a chip circuit which is separately isolated on the wafer by the DRIE process may correspond to a chip area D. As mentioned above, the scribe lane is also referred to as the DRIE area C because a DRIE process is performed onto the back side of the wafer in the scribe lane.

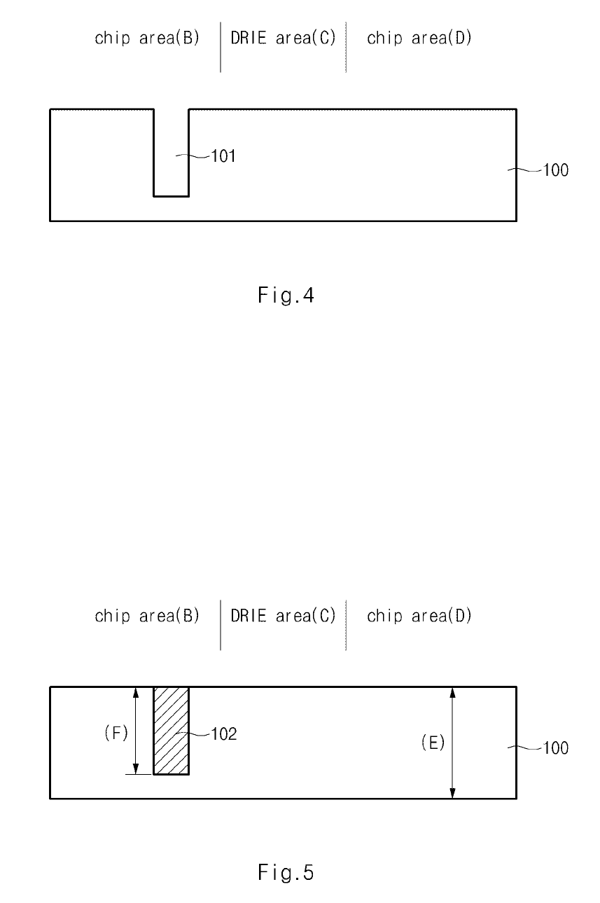

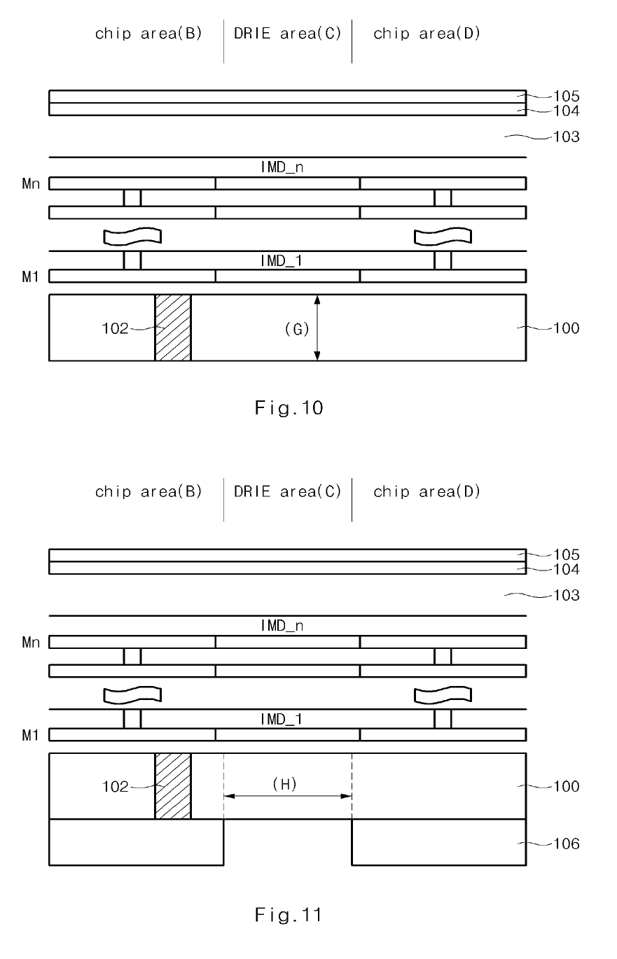

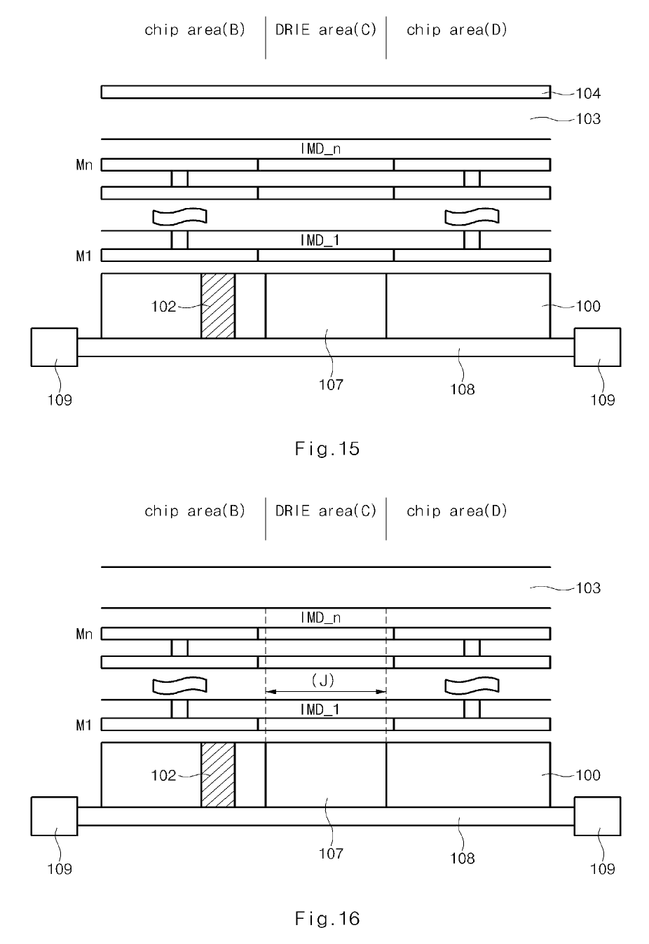

FIGS. 4 to 16 are cross-sectional views illustrating a method for forming a wafer according to an embodiment of the present invention. In more detail, FIGS. 4 to 16 are cross-sectional views taken along the line A-A′ of FIG. 3. In accordance with the embodiment of the present invention, a wafer is largely divided into a chip area B, an adjacent chip area D, and a DRIE area C formed between the chip areas B, D.

Referring to FIG. 4, a first trench 101 is formed in a chip area B of a substrate 100. It is preferable that the semiconductor substrate 100 be formed of silicon (Si), germanium (Ge), or germanium arsenide (GeAs), etc, but not limited thereto.

In order to process the photo-mask align key pattern when a mask process is performed during the backgrinding process, a process for etching a backgrinding align key trench 101 is performed prior to a CMOS process. In other words, if the backgrinding align key is exposed during the backgrinding process, the wafer forming method according to the embodiment of the present invention performs a back-side photo-mask process using the exposed backgrinding align key, such that alignment between the back side and the front side of the wafer can be adjusted.

Thereafter, as shown in FIG. 5, a filling material fills up the first trench area 101 to form a back side align key 102 (AK1). In this case, the filling material may be formed of a material, a color of which is different from that of a semiconductor substrate 100. As a result, the wafer forming method according to the embodiment of the present invention can read the align key pattern using a difference in color between the filling material and the semiconductor substrate 100 during the photo-mask process. It is preferable that the filling material has a different color from the substrate 100 so as to stand out during a photo-mask process onto the back side of the substrate 100.

It is preferable that the filling material be formed of a tungsten (W) based metal, a silicon-based oxide layer (SiO2), or a nitride layer.

Assuming that the semiconductor substrate 100 is formed about 750 μm thick (E), it is preferable that the back side align key 102 (AK1) is formed about 500 μm˜750 μm thick. It should be noted that the thickness of the semiconductor substrate 100 is not limited thereto, but is capable of being set to other values as necessary. As the wafer size is gradually increased, the semiconductor substrate 100 becomes thicker. For example, the thickness of the semiconductor substrate 100 may be set to about 600 μm, 550 μm, and the like.

The trench area 101 is deeply etched from the surface of the semiconductor substrate 100. The depth of the first trench 101 is denoted by ‘F’. The first trench 101 may be formed of a hole penetrating the semiconductor substrate.

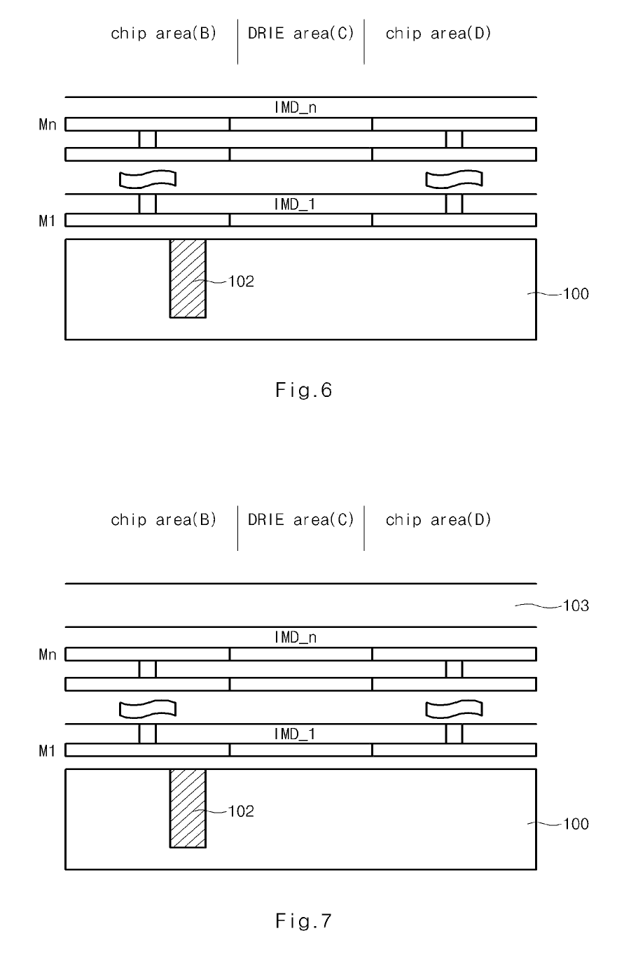

Subsequently, as shown in FIG. 6, a semiconductor circuit, for example, a CMOS circuit is formed over the semiconductor substrate 100 in the chip area B and the adjacent chip area D. If necessary, the CMOS circuit may be formed in some chip areas (B, D) but not in the other chip areas (B, D).

Several metal lines M1˜Mn are sequentially deposited in the chip area (B, D), and Inter Metal Dielectric (IMD) layers IMD_1˜IMD_n are formed in the chip area (B, D) as well.

Although the embodiment of FIG. 6 discloses a CMOS circuit that is formed in the chip area B and the chip area D, the scope and spirit of the present invention are not limited thereto. For example, the metal lines M1˜Mn formed in the CMOS circuit may be extended to the DRIE area C. Also, Inter Metal Dielectric (IMD) layers IMD_1˜IMD_n may be extend to the DRIE area C.

Next, as shown in FIG. 7, a passivation layer 103 is formed over the chip area B, the DRIE area C and the adjacent chip area D. When the front side of the wafer is turned face down to perform a back-side process, the metal lines M1˜Mn forming the CMOS circuit may be damaged due to contact with an external object. In order to protect the metal lines M1˜Mn from damage, the passivation layer 103 is formed. It is preferable that the passivation layer 103 be formed of a nitride material or a Polymide Isoindro Quirazorindione (PIQ) material.

The passivation layer 103 serves to protect the circuit formed on the front side of the substrate 100.

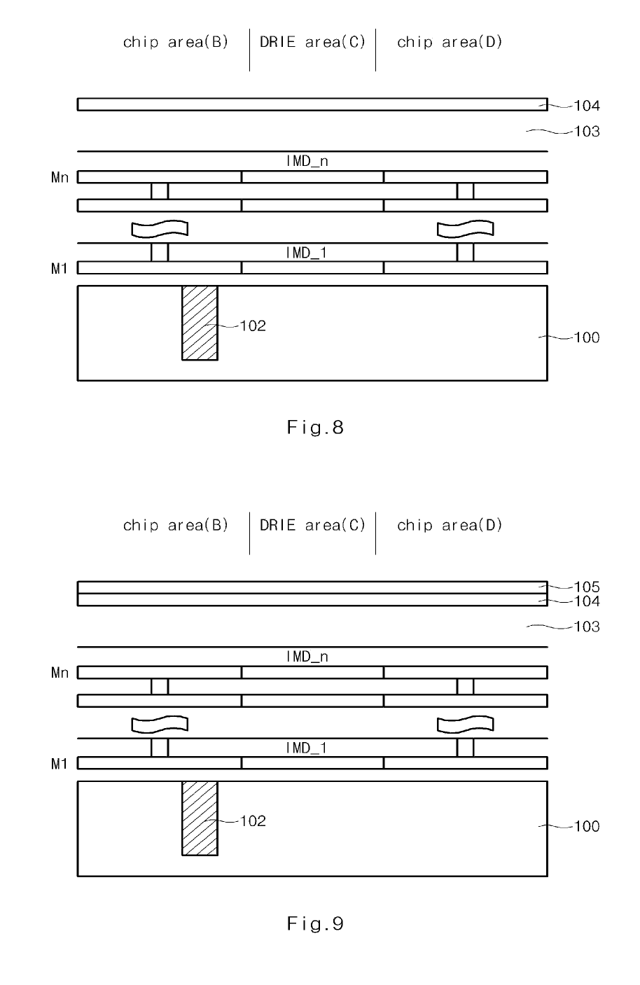

Subsequently, as shown in FIG. 8, a coating film 104 is deposited over the passivation layer 103. The coating film 104 also is formed to protect circuits formed on the front side of the substrate 100.

Thereafter, as shown in FIG. 9, a reinforcing film 105 is deposited on the coating film 104. The reinforcing film 105 serves as a physical support for protecting the wafer from stress from an external physical force. Although a physical force is applied from the outside, the reinforcing film 105 prevents the wafer from being curved.

In more detail, a physical stress caused during a back-side process such as a back-grinding process can be dispersed by the reinforcing film 105.

The reinforcing film 105 may be formed of a heat-resistant polymer layer, an aluminum foil tape, or the like.

Next, the substrate is turned over to perform a back-side process such as aback-grinding process onto the back side of the semiconductor substrate 100. The back-grinding process is performed by grinding the back side of the substrate 100 until the back-side align key 102 (AK1) is exposed.

It is desirable that the thickness of the semiconductor substrate 100 under the back-side align key 102 is about 150 μm or less. However, the thickness of the substrate 100 under the back-side align key 102 is not limited thereto, and can be about 200 μm˜300 μm.

Subsequently, as shown in FIG. 11, a photo masking process is performed to form a photoresist pattern 106 defining the DRIE area C (the scribe lane L) is formed over the semiconductor substrate 100. The photo masking process is performed using the back-side align key 102 (AK1) as a reference. The photo masking process is performed using the back-side align key 102 (AK1) as a reference. The wafer is turned over in an actual fabrication process, such that an area in which the photoresist pattern 106 is formed may correspond to an upper area of the semiconductor substrate 100. In this case, a photo-mask align key may use the backgrinding align key pattern.

The photoresist pattern 106 is formed to cover the chip area B and the chip area D, and to open the DRIE area C (i.e., H area). As a result, the align key pattern in which the filling material 102 is formed may be used as a reference key for etching the DRIE area C (i.e., H area).

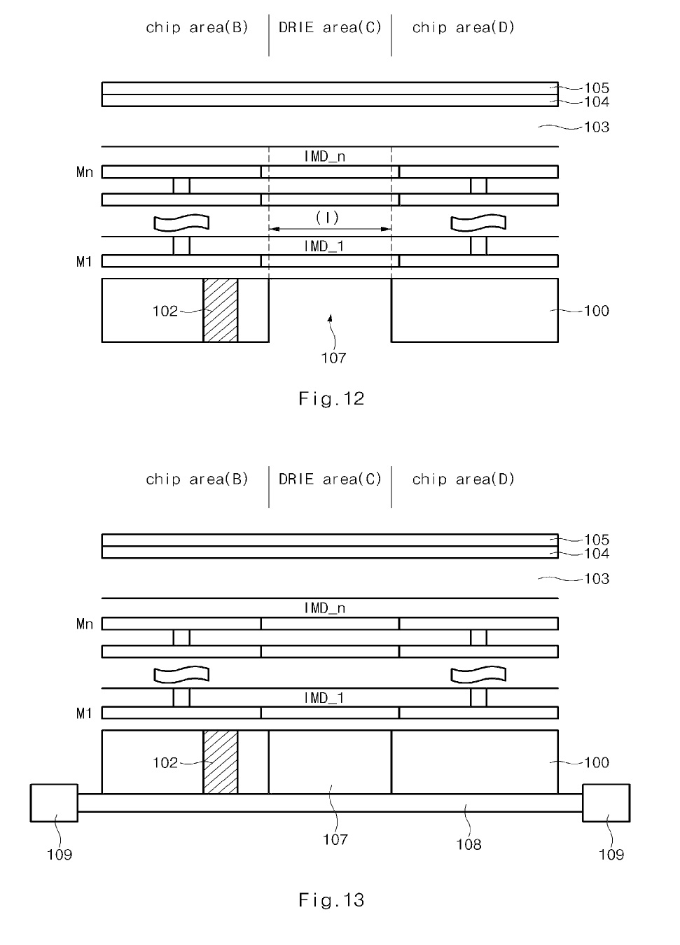

Thereafter, as shown in FIG. 12, a DRIE process is executed on the back side of the substrate using the photoresist pattern 106 as an etching mask to form a second trench 107. In other words, the H area is etched such that the trench area 107 is formed in the scribe lane L. In this case, the trench area 107 may correspond to the scribe lane L for separating each chip.

In accordance with an embodiment of the present invention, the second trench area 107 is formed by patterning by H in width the substrate 100 in the scribe lane L (DRIE area C). However, the scope or spirit of the present invention is not limited thereto, and the second trench 107 may be extended to the IMD layers IMD_1˜IMD_n by patterning by I in width the IMD layers IMD_1˜IMD_n formed over the substrate 100 in the scribe lane L (DRIE area C), as necessary.

Next, as shown in FIG. 13, a ring film 108 is formed over the back side of the semiconductor substrate 100, such that the wafer mounting process can be carried out. A ring mount 109 is formed around the ring film 108.

The ring film 108 is used as a protection film, such that it protects chips contained in the wafer while the wafer is delivered, or prevents the second trench 107 from being crushed during a subsequent packaging process. For this purpose, the ring film 108 is detachably mounted over the semiconductor substrate 100 so that the ring film 108 can be easily separated from the semiconductor substrate 100.

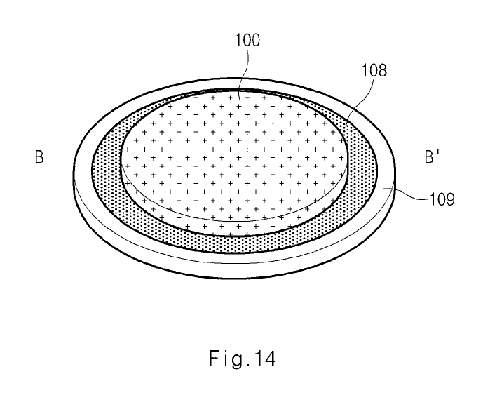

FIG. 14 is a perspective view showing the semiconductor substrate 100, the ring film 108 and the ring mount 109. FIG. 13 is a cross-sectional view taken along the line B-B′ of FIG. 14.

Referring to FIG. 14, a wafer ring frame is formed on the back side of the semiconductor substrate 100. Here, the wafer ring frame includes the donut-ring-shaped ring mount 109 and the ring film 108.

As shown, the ring mount 109 for supporting the ring film 108 is formed around the ring film 108. The back side of the semiconductor substrate 100 is in contact with the ring film 108.

In this case, in the DRIE area C, a specific area J in which IMD layers IMD_1˜IMD_n and the passivation layer 103 are formed is relatively thinner than the semiconductor substrate 100 such that the J area has a very thin thickness (i.e., a very small depth) as compared to the semiconductor substrate 100. In particular, the J area having a small thickness is considered in the same manner as in an etched status, such that it can be easily isolated.

The layer denoted with J in which IMD layers IMD_1˜IMD_n and the passivation layer 103 are formed relatively thin compared with the semiconductor substrate 100. Thus, chip areas (B, D) can be easily isolated from one another.

For example, if it is assumed that the semiconductor substrate 100 has a thickness of about 200 μm˜300 μm, the J area has a thickness of only about 3 μm. Therefore, the semiconductor substrate 100 of about 90% or more of the total thickness of substrate 100 has already been removed by the trench area 107, such that the J area can be easily isolated to make a distinction between chip areas.

Accordingly, if the substrate 100 in the scribe lane L is removed by the second trench 107, the chip area B and the other chip area D are separated from each other.

As apparent from the above description, the above-mentioned embodiments of the present invention have the following characteristics.

First, a wafer and a method for forming the same according to one embodiment of the present invention can allow each memory chip to be diced using a DRIE process without performing an additional sawing process on a wafer including a plurality of memory chips, resulting in a reduction in fabrication time and production costs.

Second, a wafer and a method for forming the same according to another aspect of the present invention can allow each RFID chip to be diced using a DRIE process without performing an additional sawing process on a wafer including a plurality of memory chips, resulting in a reduction in fabrication time and production costs.

Third, a wafer and a method for forming the same according to another aspect of the present invention can reduce an area of a scribe lane.

Fourth, according to another embodiment of the present invention, since a DRIE process can be simultaneously performed on an overall wafer, fabrication time and production cost can be significantly reduced.

Although a number of illustrative embodiments consistent with the invention have been described, it should be understood that numerous other modifications and embodiments can be devised by those skilled in the art that will fall within the spirit and scope of the principles of this disclosure. Particularly, numerous variations and modifications are possible in the component parts and/or arrangements which are within the scope of the disclosure, the drawings and the accompanying claims. In addition to variations and modifications in the component parts and/or arrangements, alternative uses will also be apparent to those skilled in the art.

What is claimed is:

1. A wafer comprising:
a plurality of chips configured to be arranged in row and column directions on the wafer;
a scribe lane configured to be formed among the plurality of chips so as to separate each chip; and
an align key pattern configured to be arranged on the plurality of chips.

2. The wafer according to claim 1, wherein each of the chips includes a radio frequency identification (RFID) chip.

3. The wafer according to claim 2, wherein the RFID chip includes a non-volatile ferroelectric memory.

4. The wafer according to claim 1, wherein the scribe lane is isolated by a Deep Reactive Ion Etching (DRIE) process.

5. The wafer according to claim 4, wherein the Deep Reactive Ion Etching (DRIE) process is performed at a back side of the wafer on a basis of the align key pattern.

6. The wafer according to claim 1, wherein the align key pattern includes:
a first align key configured to perform a backgrinding process at a back side of the wafer; and
a second align key configured to perform an integration process at a front side of the wafer.

7. The wafer according to claim 1, wherein the align key pattern is distributively arranged in a vertical or horizontal direction of a predetermined area of the plurality of chips.

8. A method for forming a wafer which includes a first chip area in which an align key pattern is formed, a second chip area, and a scribe lane for separating the first chip area and the second chip area from each other, the method comprising:
forming the align key pattern on the first chip area of a semiconductor substrate;
forming a circuit area on each of the first chip area and the second chip area of an upper part of the semiconductor substrate;
forming a passivation layer on the circuit area;
exposing the align key pattern by performing a backgrinding process at a back side of the semiconductor substrate;
forming a first trench on the semiconductor substrate formed in the scribe lane, using a photoresist pattern as an etch mask; and
performing a wafer mounting process on the semiconductor substrate including the first trench.

9. The method according to claim 8, wherein each of the first chip area and the second chip area includes a radio frequency identification (RFID) chip.

10. The method according to claim 8, wherein the forming of the align key pattern includes:
forming a second trench on the semiconductor substrate; and
burying a filling material in the second trench.

11. The method according to claim 8, wherein the filling material is different in color from the semiconductor substrate.

12. The method according to claim 8, wherein the circuit area includes a metal line extended to the scribe lane, and an Inter Metal Dielectric (IMD) layer.

13. The method according to claim 8, wherein the passivation layer is formed on each of the first chip area, the second chip area, and the scribe lane.

14. The method according to claim 8, further comprising:
forming a coating film on the passivation layer; and
forming a reinforcing film on the coating film.

15. The method according to claim 14, wherein the reinforcing film includes either of a polymer layer or an aluminum foil tape.

16. The method according to claim 8, wherein the photoresist pattern is formed on each of the first chip area and the second chip area of the semiconductor substrate.

17. The method according to claim 8, wherein the first trench is formed at a back side of the semiconductor substrate by a Deep Reactive Ion Etching (DRIE) process.

18. The method according to claim 8, wherein the first trench is etched until the passivation layer is exposed at a back side of the semiconductor substrate.

19. The method according to claim 8, wherein the mounting process includes:
forming a ring film to which the semiconductor substrate including the first trench is mounted; and
forming a ring mount around the ring film.

20. The method according to claim 8, further comprising:
after performing the mounting process, removing a coating film formed on the passivation layer, and removing a reinforcing film.
